(19) United States
(12) Patent Application Publication
(10) Pub. No.: US 2026/0371507 A1
(43) Pub. Date: Nov. 19, 2026

(54) ELECTRONIC DEVICE, AND CHASSIS AND HANDLE ASSEMBLY THEREOF

(71) Applicant: Wistron Corporation, New Taipei City (TW)

(72) Inventors: CHIN TING WAN, New Taipei City (TW); CHENG WEI CHEN, New Taipei City (TW)

(21) Appl. No.: 19/273,606

(22) Filed: Jul. 18, 2025

(30) Foreign Application Priority Data
May 15, 2025 (TW) 114118344

(51) Int. Cl. H05K 5/02; H05K 7/14

(52) U.S. Cl. CPC H05K 5/023; H05K 5/0221; H05K 7/1489

(57) ABSTRACT

An electronic device, and a chassis and a handle assembly thereof are provided. The electronic device includes a cabinet and the chassis. The chassis includes a casing and the handle assembly. The casing is slidably disposed in the cabinet. The handle assembly includes a handle, an actuating element and a matching element. The handle is rotatably connected to the casing. The actuating element is slidably connected to the handle. The matching element is disposed between the casing and the handle. The actuating element is driven to slide relative to the handle, such that the matching element is engaged with the casing.

### CROSS-REFERENCE TO RELATED APPLICATION

This non-provisional application claims priority under 35 U.S.C. § 119(a) to Patent Application No. 114118344 filed in Taiwan, R.O.C. on May 15, 2025, the entire contents of which are hereby incorporated by reference.

### BACKGROUND

### Technical Field

The disclosure relates to an electronic device, and a chassis and a handle assembly thereof.

### Related Art

In response to the rapid growth of cloud computing technology, large servers in communication and data centers may employ a cabinet-mounted design in general cases. The cabinet may be equipped with a chassis according to user requirements to expand server hardware and centrally provide functions such as power supply, fan cooling and network communication.

### SUMMARY

In order to facilitate the installation, replacement or maintenance of the chassis in the cabinet, the chassis may be provided with an assisting handle. However, the assisting handle of the chassis is often designed with a fixed angle. If the chassis is positioned at a height that is too high (for example, higher than the operator's shoulders) or too low (for example, lower than the operator's knees), the operator often performs operations in a posture that is not ergonomic. This process is not only inconvenient in use, but also easily causes structural damage of components, and even the operator is at high risk of injury.

In view of this, embodiments of the disclosure provide an electronic device, and a chassis and a handle assembly thereof.

According to some embodiments, an electronic device comprises a cabinet and a chassis. The chassis comprises a casing and a handle assembly. The casing is slidably disposed in the cabinet. The handle assembly comprises a handle, an actuating element and a matching element. The handle is rotatably connected to the casing. The actuating element is slidably connected to the handle. The matching element is disposed between the casing and the handle. The actuating element is used to slide relative to the handle, and the matching element is engaged with the casing.

According to some embodiments, a server chassis comprises a casing and a handle assembly. The handle assembly comprises a handle, an actuating element and a matching element. The handle is rotatably connected to the casing. The actuating element is slidably connected to the handle. The matching element is disposed between the casing and the handle. The actuating element is used to slide relative to the handle, and the matching element is engaged with the casing.

According to some embodiments, a handle assembly comprises a handle, an actuating element and a matching element. The actuating element is slidably connected to the handle. The matching element is movably disposed on the handle. The matching element is used to move relative to the handle through the actuating element, and the matching element is partially exposed to an unlocking hole of the actuating element.

Based on the above, in some embodiments, the handle can be rotated to a specified angle according to the operation requirement, and the handle can be positioned at this specified rotation angle. Accordingly, the operator can apply force to the chassis in a stable manner, so as to avoid injuries or component damage caused by improper force application.

### BRIEF DESCRIPTION OF THE DRAWINGS

FIG. 1 is a schematic three-dimensional view of an electronic device according to some embodiments, without showing the structure of components in a casing;

FIG. 2 is a schematic three-dimensional view of a chassis according to some embodiments, showing that a handle assembly is rotatable between a handle use position and a handle folded position along a rotation direction, where dashed lines indicate the handle assembly in the handle folded position;

FIG. 3 is a schematic exploded view of a chassis according to some embodiments;

FIG. 4 is a partial enlarged view of a handle assembly according to some embodiments in which an actuating element, a matching element and a side rod are drawn in a side-by-side arrangement, showing that a hook portion of an operating portion is located in a groove of a gripping portion, and a connecting rod and a slider are located in a sliding slot of the side rod, where the side rod is indicated by dashed lines, and the slider in an unlocked position is indicated by a dashdotted line;

FIG. 5 is a schematic partial sectional view (I) taken along line 5-5 in FIG. 2, showing that a slider is in a locked position and a matching element is engaged with a casing;

FIG. 6 is a schematic partial sectional view (II) at the same sectional position as FIG. 5, showing that a slider is in an unlocked position and a matching element is engaged with a casing;

FIG. 7 is a schematic partial sectional view (I) taken along line 7-7 in FIG. 2, showing that a slider does not abut against a matching element, an unlocking hole, the matching element and a positioning portion are aligned, and the matching element is located in the positioning portion;

FIG. 8 is a schematic partial sectional view (II) at the same sectional position as FIG. 7, showing that a matching element is away from a positioning portion and located in an unlocking hole, and the matching element is disengaged from a casing; and

FIG. 9 is a schematic partial sectional view (III) at the same sectional position as FIG. 7, showing that a slider does not abut against a matching element, the matching element is disengaged from a casing, and the matching element moves from an unlocking hole to a positioning portion along a chamfer of the positioning portion.

### DETAILED DESCRIPTION

Unless otherwise specified as electrical link or signal transmission, the term “connection” used in the following embodiments may be a physical connection, or a direct connection or indirect connection between physical components. In addition, the drawings of the disclosure are only for schematic illustration, and are not necessarily drawn to scale, and all details are not necessarily presented in the drawings.

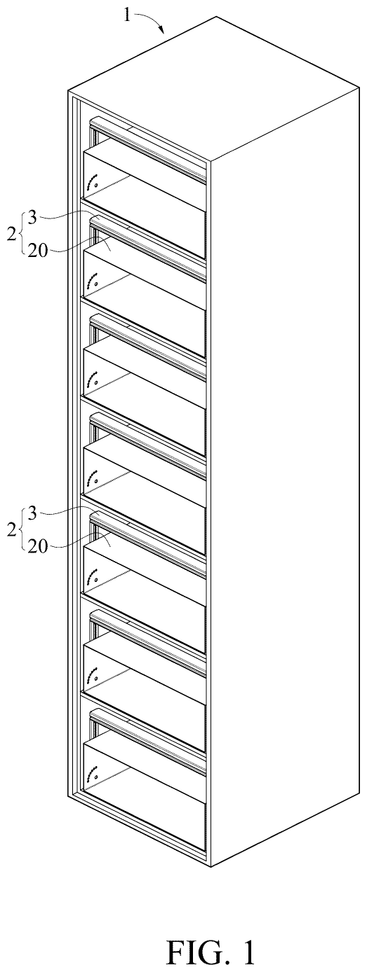

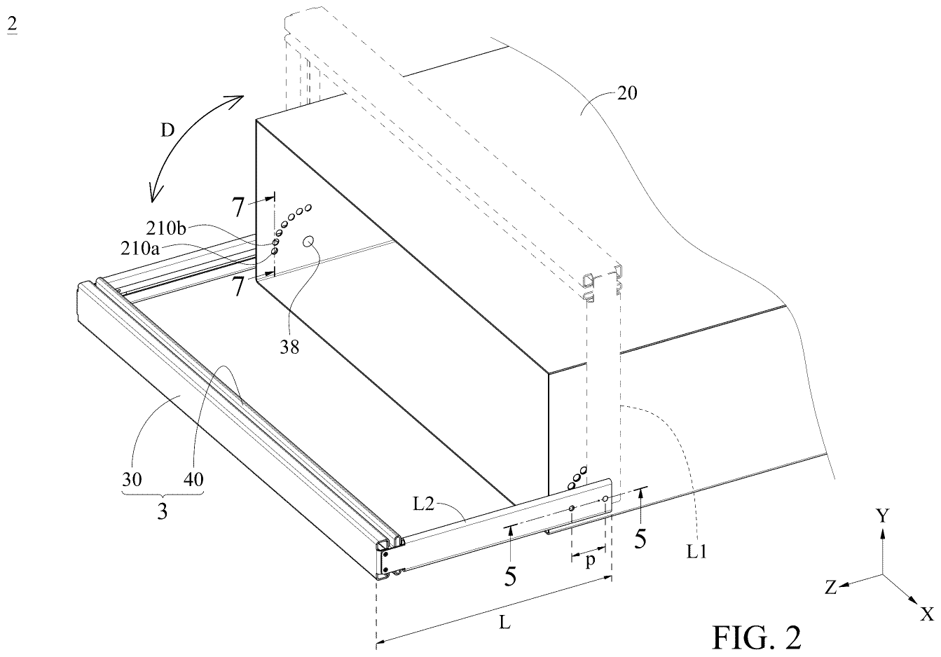

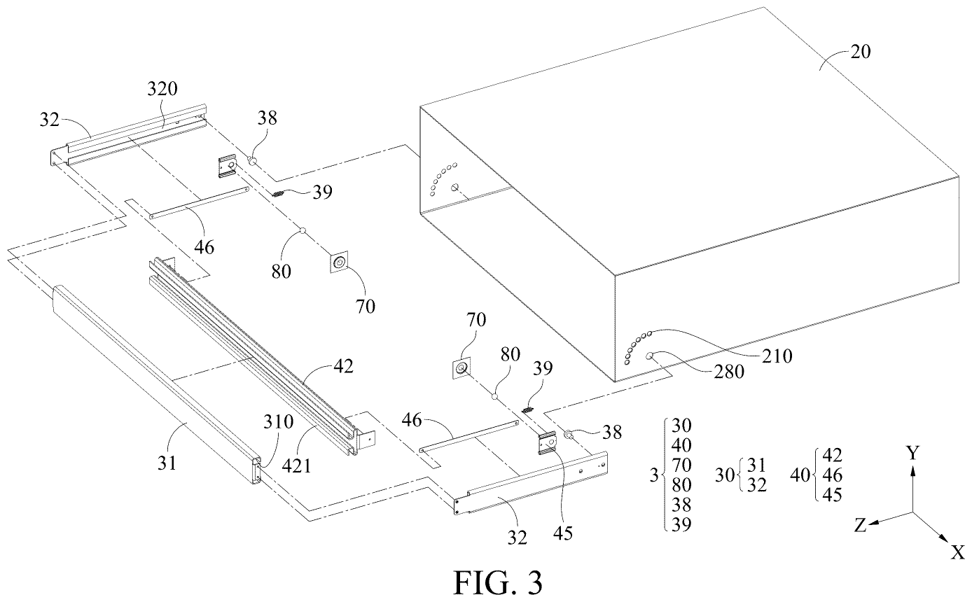

Referring to FIG. 1, FIG. 2 and FIG. 3, FIG. 1 is a schematic three-dimensional view of an electronic device according to some embodiments, without showing the structure of components in a casing 20. FIG. 2 is a schematic three-dimensional view of a chassis 2 according to some embodiments, showing that a handle assembly 3 is rotatable between a handle use position L2 and a handle folded position L1 along a rotation direction D, where dashed lines indicate the handle assembly in the handle folded position L1. FIG. 3 is a schematic exploded view of the chassis 2 according to some embodiments.

Referring to FIG. 1, an electronic device includes a cabinet 1 and a chassis 2. The electronic device is, for example, but not limited to, a tower server, a rack server, a blade server or a cabinet server. The chassis 2 may be a server chassis, and is used to install an expansion module (not shown). The expansion module may be, but not limited to, a computer hard disk, a display adapter and an expansion card. The following embodiments will describe the “chassis 2”.

Referring to FIG. 2, the chassis 2 includes a casing 20 and a handle assembly 3. The handle assembly 3 is used to be installed on the server chassis. The casing 20 is slidably disposed in the cabinet 1 (shown in FIG. 1). Taking FIG. 1 as an example, the cabinet 1 or the casing 20 may be provided with a slide rail (not shown). The chassis 2 may be slidably disposed in the cabinet 1. The cabinet 1 is provided with multiple drawer-type chassis 2, and the chassis 2 may be drawn out of the cabinet 1.

Referring to FIG. 3, the handle assembly 3 includes a handle 30, an actuating element 40 and a matching element 80, and the handle 30 is rotatably connected to the casing 20. Referring to FIG. 2, the handle 30 is operable to rotate in the rotational direction D between the handle use position L2 and the handle storage position L1. The handle storage position L1 may be positioned at different rotation angles according to the operator's requirement. Details will be explained later.

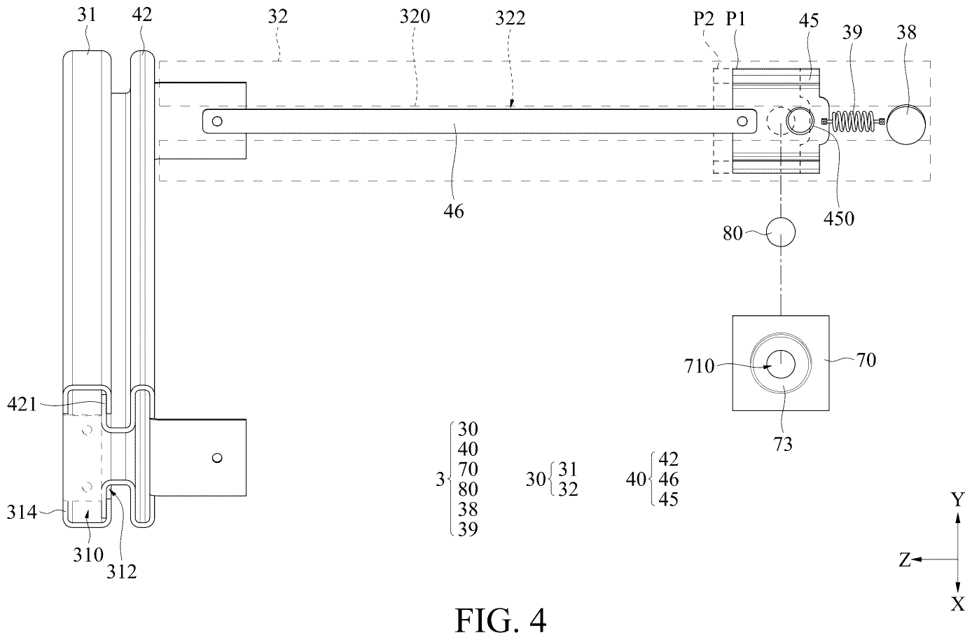

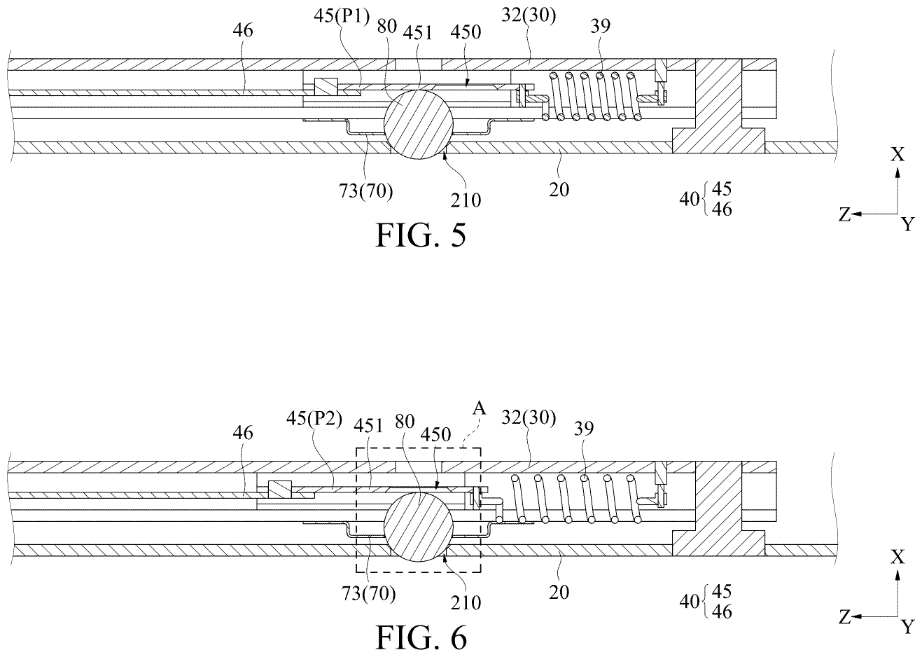

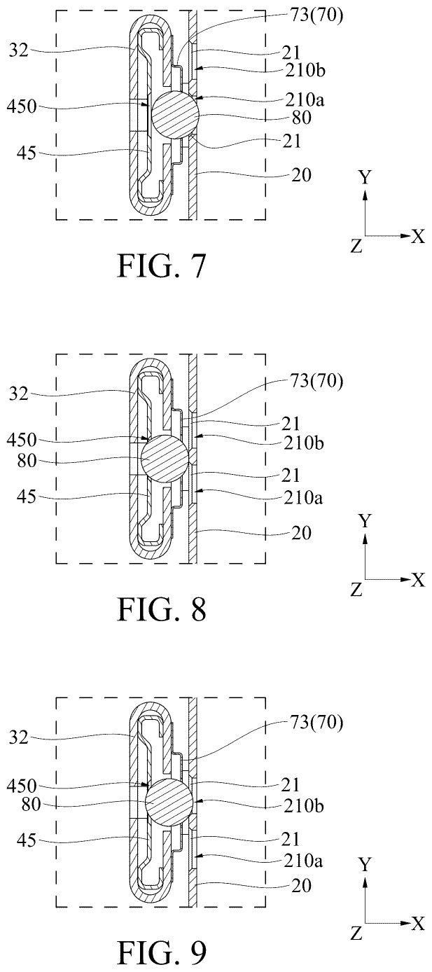

Referring to FIG. 4, FIG. 5, FIG. 6 and FIG. 8, FIG. 4 is a partial enlarged view of the handle assembly 3 according to some embodiments in which the actuating element 40, the matching element 80 and the side rod 32 are drawn in a side-by-side arrangement, showing that a hook portion 421 of an operating portion 42 is located in a groove 310 of a gripping portion 31, and a connecting rod 46 and a slider 45 are located in a sliding slot 320 of the side rod 32, where the side rod 32 is indicated by dashed lines, and the slider 45 in an unlocked position P2 is indicated by a dash-dotted line. FIG. 5 is a schematic partial sectional view (I) taken along line 5-5 in FIG. 2, showing that the slider 45 is in a locked position P1, and the matching element 80 is engaged with the casing 20. FIG. 6 is a schematic partial sectional view (II) at the same sectional position as FIG. 5, showing that the slider 45 is in the unlocked position P2, and the matching element 80 is engaged with the casing 20. FIG. 8 is a schematic partial sectional view (II) at the same sectional position as FIG. 7, showing that the matching element 80 is away from the positioning portion 210a and located in the unlocking hole 450, and the matching element 80 is disengaged from the casing 20.

Referring to FIG. 3 and FIG. 4, the actuating element 40 is slidably connected to the handle 30 (detailed later), the matching element 80 is disposed between the casing 20 and the handle 30 (shown in FIG. 5), and the matching element 80 is movably disposed on the handle 30. The actuating element 40 is used to slide relative to the handle 30, such that the matching element 80 is engaged with the casing 20 (shown in FIG. 5). In some embodiments, the matching element 80 is moved relative to the handle 30 through the actuating element 40, such that the matching element 80 is partially exposed to the unlocking hole 450 of the actuating element 40. For example, referring to FIG. 5 and FIG. 6, as result of the actuating element 40 sliding relative to the handle 30, the actuating element 40 makes the matching element 80 selectively engaged with the casing 20. FIG. 5 and FIG. 6 show the matching element 80 engaged with the casing 20, and FIG. 8 shows the matching element 80 disengaged from the casing 20. The actuating element 40 selectively abuts against the matching element 80. FIG. 5 shows the actuating element 40 abutting against the matching element 80, and FIG. 6 shows the actuating element 40 not abutting against the matching element 80. In this way, the handle 30 is rotatable to a specified angle according to the operation requirement, and the handle 30 may be positioned at this specified rotation angle. Accordingly, the operator can apply force to the chassis 2 in a stable manner, so as to avoid injuries or component damage caused by improper force application.

Referring to FIG. 3, in some embodiments, the handle 30 includes a gripping portion 31 and a side rod 32, and two ends of the side rod 32 are respectively connected to the gripping portion 31 and the casing 20. The actuating element 40 includes an operating portion 42, a connecting rod 46 and a slider 45. Two ends of the connecting rod 46 are respectively connected to the operating portion 42 and the slider 45. The slider 45 is disposed on the side rod 32 of the handle 30. The connecting rod 46 is slidably connected to a sliding slot 320 of the side rod 32, such that the connecting rod 46 is movable relative to the side rod 32 along a Z-axis direction in the drawing. The operating portion 42 is movably connected to the gripping portion 31, such that the operating portion 42 is movable relative to the gripping portion 31 along the Z-axis direction in the drawing. Therefore, the operating portion 42 moves relative to the gripping portion 31 along the Z-axis direction, such that the operating portion 42 causes the connecting rod 46 and the slider 45 to moves relative to the side rod 32 along the Z-axis direction. Referring to FIG. 4, the actuating element 40 is slidably connected to the handle 30 and has a locked position P1 and an unlocked position P2. For example, the actuating element 40 is slidably disposed in the sliding slot 320 of the handle 30. When the actuating element 40 is operated to move along the +Z-axis direction, the slider 45 of the actuating element 40 slides from the locked position P1 to the unlocked position P2. The locked position P1 is a normal position when the actuating element 40 (slider 45) is not in operation, and the unlocked position P2 is any position other than the locked position P1.

Referring to FIG. 5, the actuating element 40 is provided with an unlocking hole 450 and an abutting portion 451. When the actuating element 40 is in the locked position P1, the abutting portion 451 of the actuating element 40 abuts against the matching element 80. The matching element 80 is engaged with the positioning portion 210 of the casing 20, and the handle 30 is fixed to the casing 20 (i.e., the handle 30 is not rotatable relative to the casing 20). Referring to FIG. 6, when the actuating element 40 is in the unlocked position P2, the unlocking hole 450 of the actuating element 40 corresponds to the matching element 80. The matching element 80 has a degree of freedom of movement along at least an X-axis in the drawing, and the matching element 80 is not locked to the casing 20. In some embodiments, the corresponding relationship between the unlocking hole 450 and the matching element 80 refers to the positions alignment. For example, referring to FIG. 5, when the slider 45 (actuating element 40) is in the locked position P1, the unlocking hole 450 of the slider 45 is misaligned with the matching element 80. The abutting portion 451 of the slider 45 abuts against the matching element 80, and the matching element 80 is pushed toward the casing 20 by the abutting portion 451, hereby the matching element 80 engaged with the positioning portion 210. Referring to FIG. 6, when the slider 45 (actuating element 40) is in the unlocked position P2, the unlocking hole 450 of the slider 45 is aligned with the matching element 80, to provide a buffer space for the matching element 80, thereby allowing the matching element 80 with a degree of freedom of movement to be disengaged from or detached from the positioning portion 210 of the casing 20, such as a movement margin along an +X-axis direction in FIG. 6. Referring to FIG. 8, when the slider 45 is located in the unlocked position P2, the matching element 80 is not disengaged from or detached from the positioning portion 210.

In this way, when the actuating element 40 is not operated, the handle 30 can be stably positioned at a specified position, allowing the operator to exert force to pull out or push in the chassis 2 into the cabinet 1. In other words, the operator may easily operate the actuating element 40 to change the position of the handle 30, providing convenience in operation.

Structural details of the chassis 2 will be described below with some embodiments.

Referring to FIG. 3, in some embodiments, the handle assembly 3 includes a shaft 38. The shaft 38 passes through the side rod 32 and a shaft hole 280 of the casing 20. The side rod 32 (handle 30) is pivoted to the casing 20, and is rotatably connected to the casing 20, In addition, the casing 20 includes multiple positioning portions 210. For example, one side of the casing 20 is provided with at least three positioning portions 210. The positioning portions 210 are, for example, but not limited to, circular holes. The positioning portions 210 are arranged along the rotation trajectory of the handle 30 (side rod 32) with the shaft 38 as the center and at the same radius. That is, each positioning portion 210 is at the same distance from the center of the shaft 38. Taking FIG. 3 as an example, the casing 20 is provided with seven positioning portions 210, and the rotation angle between every two adjacent positioning portions 210 is about 15 degrees. In other words, the handle 30 of FIG. 2 has six handle use positions L2, and the rotation angle between every two adjacent handle use positions L2 is about 15 degrees. Therefore, the handle assembly 3 has a multi-angle limiting function. The operator can fix the handle 30 at an appropriate rotation angle for operation, and the friendliness of operation can be provided.

Referring to FIG. 4, the side rod 32 of the handle 30 is provided with a sliding slot 320. The gripping portion 31 of the handle 30 is provided with a groove 310. A opening 322 of the sliding slot 320 and a opening 312 of the groove 310 are both oriented toward the casing 20 (shown in FIG. 3). Referring to FIG. 5, the matching element 80 is disposed between the slider 45 and the casing 20. The slider 45 of the actuating element 40 is provided with an unlocking hole 450 and an abutting portion 451. The abutting portion 451 is located at the periphery of the unlocking hole 450. The abutting portion 451 is the position where the slider 45 abuts against the matching element 80. Referring to FIG. 4, the connecting rod 46 and the slider 45 are slidably disposed in the sliding slot 320, and the matching element 80 is located at the opening 322 of the sliding slot 320. In addition, the operating portion 42 of the actuating element 40 is connected to the groove 310 of the handle 30. The operating portion 42 is provided with a hook portion 421, which is disposed in the groove 310 of the gripping portion 31 of the handle 30. The hook portion 421 is operable to be close to or away from the opening 312 of the groove 310. For example, the hook portion 421 of the operating portion 42 is hooked to the opening 312 of the groove 310 of the gripping portion 31. When the operating portion 42 is pressed, the hook portion 421 moves away from the opening 312 of the groove 310 and toward the bottom side 314 of the groove 310. The opening 312 of the groove 310 and the bottom side 314 of the groove 310 are respectively two opposite sides of the gripping portion 31. For example, the operating portion 42 has a degree of freedom of movement relative to the gripping portion 31 along the Z-axis, and the operating portion 42 is movably close to the gripping portion 31 of the handle 30 along the +Z-axis direction, so as to drive the slider 45 to move toward the unlocked position P2. In some embodiments, two side rods 32 are connected to two ends of the gripping portion 31. Two ends of the operating portion 42 are respectively connected to one end of each of the two connecting rods 46, and the other end of each of the two connecting rods 46 is respectively connected to each of the two sliders 45. In this way, the connecting rods 46 are slidably disposed in the side rods 32. The handle 30 is not limited to be U-shaped (as shown in FIG. 3), and may be other variations. For example, the chassis 2 is provided with at least one L-shaped handle 30, and the inner side of the handle 30 is provided with the actuating element 40. The hook portion 421 of the operating portion 42 is not limited to be a double concave shape (as shown in FIG. 3), and may also be other variations. It should be noted that the actuating element 40 (i.e., the connection among the connecting rod 46, the operating portion 42 and the slider 45) and the handle 30 (i.e., the connection between the side rod 32 and the gripping portion 31) can be integrally formed, or connected through fasteners (for example, but not limited to screws, rivets or hooks).

Referring to FIG. 3 and FIG. 4, in some embodiments, the handle assembly 3 further includes a stop element 70. The stop element 70 is disposed on the side rod 32 of the handle 30. The stop element 70 is provided with an accommodating hole 710. The matching element 80 is disposed between the stop element 70 and the slider 45, and a part of the matching element 80 is exposed to the accommodating hole 710. Taking FIG. 4 as an example, the diameter of the accommodating hole 710 is less than the diameter of the matching element 80. When the stop element 70 covers the matching element 80, a part of the matching element 80 is exposed to the accommodating hole 710 of the stop element 70, and this exposed part of the matching element 80 is engaged with the positioning portion 210 (shown in FIG. 7) or be in contact with the surface of the casing 20 (shown in FIG. 8). Accordingly, the stop element 70 is used to limit the position of the matching element 80, for example, by limiting the position of the matching element 80 to a position along the Z-axis, so as to prevent the matching element 80 from being disengaging from the side rod 32.

Specifically, referring to FIG. 5 and FIG. 6, in some embodiments, the stop element 70 further includes a protruding portion 73. The protruding portion 73 protrudes toward the casing 20, and the accommodating hole 710 is located at the protruding portion 73 (shown in FIG. 4). Therefore, the protruding portion 73 can enhance the limiting effect of the stop element 70 on the matching element 80. The distance between the side rod 32 and the casing 20 (for example, the distance along the X-axis) can be increased to avoid assembly hindrance caused by component tolerances.

In some embodiments, the matching element 80 includes a ball. The diameter of the unlocking hole 450 of the actuating element 40 is about 0.6 to 0.9 times the diameter of the ball. The diameter of the ball is directly proportional to a load-bearing weight of the chassis 2. The diameter of the ball satisfies to the following formula:

D=(F/(k×P×L))×R

In the formula, D represents the diameter of the ball. F represents radial force applied to the handle 30, which ranges between 5 kg and 70 kg. k represents a friction coefficient of the ball. P represents a lead p of the actuating element 40. L represents an effective length of the handle 30. and R represents a range parameter, which ranges between 0.75 and 1.25. In some embodiments, preferably the radial force ranges between 12 kg and 60 kg.

Referring to FIG. 2, for example, when the handle 30 is in the handle use position L2, the handle 30 is parallel to the Z-axis (or the rotation angle is 0), and the effective length L of the handle 30 is 10 mm. Given that the lead p is 30 mm, the friction coefficient of the ball is 0.2 and the diameter of the ball is 2 mm, the radial force applied to the handle 30 will be 12 kg. If the diameter of the ball in the foregoing exemplary embodiment becomes to 10 mm, the radial force applied to the handle 30 will be 60 kg. Therefore, the appropriate size of the ball (or matching element 80) can be designed according to the radial force required for pulling the chassis 2.

Referring to FIG. 4, in some embodiments, the handle assembly 3 further includes a reset element 39. The reset element 39 is connected to the slider 45 and the side rod 32. The reset element 39 is used to maintain the actuating element 40 in the locked position P1. The reset element 39 provides force to normally maintain the actuating element 40 in the locked position P1. The reset element 39 is, for example, but not limited to, a spring, a leaf spring, a torsion spring and an elastic component capable of generating a restoring force due to deformation. Specifically, the reset element 39 provides force to pull the slider 45 and the hook portion 421 of the operating portion 42 toward a-Z-axis direction. In some embodiments, normally, the actuating element 40 is in the locked position P1, and the hook portion 421 of the operating portion 42 is substantially in contact with the gripping portion 31 (the opening 312 of the groove 310), as shown in FIG. 4. When the operating portion 42 is operated, the hook portion 421 is pushed toward the bottom side of the groove 310 along the +Z-axis direction.

Referring to FIG. 2, FIG. 5 and FIG. 6, in some embodiments, the casing 20 includes multiple positioning portions 210. The reset element 39 is used to make the actuating element 40 slide from the unlocked position P2 to the locked position P1, and the matching element 80 is positioned in one of the positioning portions 210 by the abutting portion 451 of the actuating element 40. Specifically, when the actuating element 40 (slider 45) is in the unlocked position P2, the handle 30 is rotatable relative to the casing 20. When the handle 30 is rotated relative to the casing 20 and the matching element 80 corresponds to one of the positioning portions 210, the reset element 39 makes the actuating element 40 slide toward the locked position P1. Accordingly, the abutting portion 451 of the actuating element 40 abuts against the matching element 80, and thereby, the matching element 80 is engaged with the corresponding positioning portion 210. In this embodiment, the expression of “the handle 30 is rotated relative to the casing 20 and the matching element 80 corresponds to the positioning portion 210” may refer to a status in which the handle 30 is operable to rotate and the matching element 80 has a degree of freedom of movement along at least one axis so as to be disengaged from the casing 20. In this case, a part of the matching element 80 may be located in the positioning portion 210 and have a margin of movement along the +X-axis (for example, as shown in FIG. 6), or the matching element 80 enters the corresponding positioning portion 210 along a chamfer 21 (for example, as shown in FIG. 9).

Details of actuation between the components when the handle assembly 3 is operated will be described below with some embodiments.

Referring to FIG. 7 and FIG. 9, FIG. 7 is a schematic partial sectional view (I) taken along line 7-7 in FIG. 2, showing that the slider 45 does not abut against the matching element 80, the unlocking hole 450, the matching element 80 and the positioning portion 210a are aligned, and the matching element 80 is located in the positioning portion 210a. FIG. 9 is a schematic partial sectional view (III) at the same sectional position as FIG. 7, showing that the slider 45 does not abut against the matching element 80, the matching element 80 is not locked to the casing 20, and the matching element 80 moves from the unlocking hole 450 to the positioning portion 210b along a chamfer 21 of the positioning portion 210b.

Referring to FIG. 2, FIG. 4, FIG. 7, FIG. 8, FIG. 9 and FIG. 5 in sequence, in some embodiments, referring to FIG. 2, the operator wants to change the handle use position L2 of the handle 30 and rotate the handle 30 from the positioning portion 210a to the positioning portion 210b. Referring to FIG. 4, first, the operator presses the actuating element 40, such that the operating portion 42 moves close to the gripping portion 31 along the +Z-axis and the slider 45 is driven to move from the locked position P1 to the unlocked position P2 along the +Z-axis. Referring to FIG. 7, when the slider 45 is in the unlocked position P2 (i.e., the slider 45 does not abut against the matching element 80), the unlocking hole 450, the matching element 80 and the positioning portion 210a are aligned. At this time, the matching element 80 engaged with the positioning portion 210a will have a margin of movement toward the slider 45 (unlocking hole 450). In other words, as long as the operator continues to press the actuating element 40 and keep the slider 45 in the unlocked position P2, the handle 30 can be rotatable. In this stage, the matching element 80 has not yet entered the unlocking hole 450. Next, the operator rotates the handle 30. Referring to FIG. 8, when the handle 30 is operated to rotate from the positioning portion 210a to the positioning portion 210b, the matching element 80 is pushed by the casing 20 and disengaged from the positioning portion 210a, so that a part of the matching element 80 is located in the unlocking hole 450. In other words, during the rotation of the handle 30, the matching element 80 is driven by the rotation to move and collide with the casing 20. Specifically, the chamfer 21 of the positioning portion 210a abuts against the matching element 80, and the matching element 80 is disengaged from the positioning portion 210a. Then, the matching element 80 is substantially in contact with the surface of the casing 20 between the positioning portions 210a and 210b, and a part of the matching element 80 enters the unlocking hole 450.

After that, referring to FIG. 9, the matching element 80 driven by the rotation moves and enters the positioning portion 210b along the chamfer 21 of the positioning portion 210b. Then, referring to FIG. 5, the matching element 80 has entered the positioning portion 210b. Finally, the operator releases the actuating element 40. The reset element 39 drives the slider 45 slide toward the locked position P1. The abutting portion 451 of the slider 45 abuts against the matching element 80, and the matching element 80 is engaged with the positioning portion 210b, thereby the handle 30 fixed to the casing 20. Then, the operator can apply force to the chassis 2 in the stable manner and pull the chassis 2 out of the cabinet 1 for performing disassembly or installation.

Although the disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. An electronic device, comprising:
a cabinet; and
a chassis, comprising:
a casing, slidably disposed in the cabinet; and
a handle assembly, comprising:
a handle, rotatably connected to the casing;
an actuating element, slidably connected to the handle; and
a matching element, disposed between the casing and the handle,
wherein the actuating element is driven to slide relative to the handle, and the matching element is engaged with the casing.

2. The electronic device according to claim 1, wherein the actuating element is slidably connected to the handle and has a locked position and an unlocked position; and wherein, in the locked position, an abutting portion of the actuating element abuts against the matching element, and the matching element is engaged with the casing; and
in the unlocked position, an unlocking hole of the actuating element corresponds to the matching element, and the matching element has a degree of freedom of movement along at least one axis.

3. The electronic device according to claim 2, wherein the handle assembly further comprises a reset element, the handle comprises a side rod, and the actuating element comprises a slider; and wherein the slider is disposed on the side rod, and the reset element is connected to the slider and the side rod, and is used to maintain the actuating element in the locked position.

4. The electronic device according to claim 3, wherein the casing comprises a plurality of positioning portions, the actuating element is driven to slide from the unlocked position to the locked position by the reset element, and the matching element is positioned in one of the plurality of positioning portions by the abutting portion of the actuating element.

5. The electronic device according to claim 1, wherein the actuating element comprises an operating portion and a slider, the operating portion is connected to the slider, and the slider is provided with an unlocking hole and an abutting portion;
wherein the handle comprises a gripping portion and a side rod, the gripping portion is connected to the side rod, the gripping portion is provided with a groove, the side rod is rotatably connected to the casing, and the side rod is provided with a sliding slot; and
wherein the operating portion of the actuating element is connected to the groove of the handle, the slider of the actuating element is disposed in the sliding slot of the handle, and the matching element is disposed between the slider and the casing.

6. The electronic device according to claim 5, wherein the handle assembly further comprises a stop element, the stop element is disposed on the side rod of the handle, and the stop element is provided with an accommodating hole; and wherein the matching element is disposed between the stop element and the slider, and a part of the matching element is exposed to the accommodating hole.

7. The electronic device according to claim 6, wherein the stop element further comprises a protruding portion, the protruding portion extends toward the casing, and the accommodating hole is located at the protruding portion.

8. The electronic device according to claim 5, wherein the matching element comprises a ball, a diameter of the unlocking hole of the actuating element is about 0.6 to 0.9 times a diameter of the ball, the diameter of the ball is proportional to a load-bearing weight of the chassis, and the diameter of the ball satisfies to the following formula:
D=(F/(k×P×L))×R
wherein D represents the diameter of the ball, F represents a radial force applied to the handle, which ranges between 5 kg and 70 kg, k represents a friction coefficient of the ball, P represents a lead of the actuating element, L represents an effective length of the handle, and R represents a range parameter, which ranges between 0.75 and 1.25.

9. A server chassis, comprising:
a casing; and
a handle assembly, comprising:
a handle, rotatably connected to the casing;
an actuating element, slidably connected to the handle; and
a matching element, disposed between the casing and the handle,
wherein the actuating element is driven to slide relative to the handle, and the matching element is engaged with the casing.

10. The server chassis according to claim 9, wherein the actuating element is slidably connected to the handle and has a locked position and an unlocked position; and wherein in the locked position, an abutting portion of the actuating element abuts against the matching element, and the matching element is engaged with the casing; and
in the unlocked position, an unlocking hole of the actuating element corresponds to the matching element, and the matching element has a degree of freedom of movement along at least one axis.

11. The server chassis according to claim 10, wherein the handle assembly further comprises a reset element, the handle comprises a side rod, and the actuating element comprises a slider; wherein the slider is disposed on the side rod, the reset element is connected to the slider and the side rod, and the reset element is used to maintain the actuating element in the locked position; and
wherein the casing comprises a plurality of positioning portions, the actuating element is driven to slide from the unlocked position to the locked position by the reset element, and the matching element is positioned in one of the plurality of positioning portions by the abutting portion of the actuating element.

12. The server chassis according to claim 9, wherein the actuating element comprises an operating portion and a slider, the operating portion is connected to the slider, and the slider is provided with an unlocking hole and an abutting portion;
wherein the handle comprises a gripping portion and a side rod, the gripping portion is connected to the side rod, the gripping portion is provided with a groove, the side rod is rotatably connected to the casing, and the side rod having a sliding slot; and
wherein the operating portion of the actuating element is connected to the groove of the handle, the slider of the actuating element is disposed in the sliding slot of the handle, and the matching element is disposed between the slider and the casing.

13. The server chassis according to claim 12, wherein the handle assembly further comprises a stop element, the stop element is disposed on the side rod of the handle, and the stop element is provided with an accommodating hole; and wherein the matching element is disposed between the stop element and the slider, and a part of the matching element is exposed to the accommodating hole.

14. The server chassis according to claim 13, wherein the stop element comprises a protruding portion, the protruding portion extends toward the casing, and the accommodating hole is located at the protruding portion.

15. The server chassis according to claim 9, wherein the actuating element is slidably connected to the handle and has a locked position and an unlocked position; wherein in the locked position, an abutting portion of the actuating element abuts against the matching element, and the matching element is engaged with the casing; and
in the unlocked position, an unlocking hole of the actuating element corresponds to the matching element, and the matching element has a degree of freedom of movement along at least one axis;
wherein the handle assembly further comprises a reset element, the handle comprises a side rod, and the actuating element comprises a slider; wherein the slider is disposed on the side rod, the reset element is connected to the slider and the side rod, and the reset element is used to maintain the actuating element in the locked position;
wherein the casing comprises a plurality of positioning portions, the actuating element is driven to slide from the unlocked position to the locked position by the reset element, and the matching element is positioned in one of the plurality of positioning portions by the abutting portion of the actuating element;
wherein the actuating element further comprises an operating portion, the operating portion is connected to the slider, and the slider is provided with an unlocking hole and an abutting portion;
wherein the handle comprises a gripping portion, the gripping portion being connected to the side rod, the gripping portion is provided with a groove, the side rod is rotatably connected to the casing, the side rod is provided with a sliding slot, the operating portion of the actuating element is disposed in the groove of the handle, the slider of the actuating element is disposed in the sliding slot of the handle, and the matching element is disposed between the slider and the casing;
wherein the handle assembly further comprises a stop element, the stop element is disposed on the side rod of the handle, and the stop element is provided with an accommodating hole; wherein the matching element is disposed between the stop element and the slider, and a part of the matching element is exposed to the accommodating hole; and
wherein the stop element comprises a protruding portion, the protruding portion extends toward the casing, and the accommodating hole is located at the protruding portion.

16. A handle assembly, comprising:
a handle;
an actuating element, slidably connected to the handle; and
a matching element, movably disposed on the handle,
wherein the matching element is driven to move relative to the handle through the actuating element, and the matching element is partially exposed to an unlocking hole of the actuating element.

17. The handle assembly according to claim 16, wherein the actuating element is slidably connected to the handle and has a locked position and an unlocked position; and wherein in the locked position, an abutting portion of the actuating element abuts against the matching element; and
in the unlocked position, the matching element is partially exposed to the unlocking hole of the actuating element, and the matching element has a degree of freedom of movement toward the unlocking hole.

18. The handle assembly according to claim 17, further comprising a reset element, the handle further comprising a side rod, and the actuating element comprising a slider; and wherein the slider is disposed on the side rod, the reset element is connected to the slider and the side rod, the actuating element is driven to slide from the unlocked position to the locked position by the reset element, and the abutting portion of the actuating element abuts against the matching element.

19. The handle assembly according to claim 16, wherein the actuating element comprises an operating portion and a slider, the operating portion is connected to the slider, and the slider is provided with an abutting portion;
wherein the handle comprises a gripping portion and a side rod, the gripping portion is connected to the side rod, the gripping portion is provided with a groove, and the side rod is provided with a sliding slot; and wherein the operating portion of the actuating element is connected to the groove of the handle, the slider of the actuating element is slidably disposed in the sliding slot of the handle, and the matching element is located in the sliding slot.

20. The handle assembly according to claim 19, wherein the handle assembly comprises a stop element, the stop element is disposed on the side rod of the handle, and the stop element is provided with an accommodating hole; and wherein the matching element is disposed between the stop element and the slider, and a part of the matching element is exposed to the accommodating hole.
